(19) United States
(12) Patent Application Publication
(10) Pub. No.: US 2025/0343130 A1
(43) Pub. Date: Nov. 6, 2025

(54) POWER MODULE AND MANUFACTURING METHOD THEREFOR

(71) Applicant: AMOGREENTECH CO., LTD., Gimpo-si, Gyeonggi-do (KR)

(72) Inventor: Jihyung LEE, Gimpo-si (KR)

(73) Assignee: AMOGREENTECH CO., LTD., Gimpo-si, Gyeonggi-do (KR)

(21) Appl. No.: 18/879,436

(22) PCT Filed: Jun. 15, 2023
(86) PCT No.: PCT/KR2023/008233

§ 371 Date: Dec. 27, 2024

(30) Foreign Application Priority Data
Jun. 30, 2022 (KR) 10-2022-0080490

(51) Int. Cl. H01L 23/498; H01L 21/027; H01L 21/28; H01L 21/48; H01L 23/00; H01L 23/15; H01L 23/24

(52) U.S. Cl. CPC H01L 23/49861; H01L 21/0274; H01L 21/28123; H01L 21/4828; H01L 21/4842; H01L 23/15; H01L 23/24; H01L 23/49833; H01L 23/49844; H01L 24/08; H01L 2224/08225

(57) ABSTRACT

The present invention relates to a power module and a manufacturing method therefor. The power module of the present invention is a doubled-sided type power module, wherein a spacer-integrated ceramic substrate is arranged on an upper portion of the power module with a semiconductor chip therebetween, and a lead frame-integrated ceramic substrate is arranged on a lower portion thereof, thereby maximizing a heat dissipation effect, easily controlling the thickness of a lead frame, and improving electrical characteristics. In addition, the present invention may improve electrical conductivity by forming an electrode pattern part integrated with a first circuit pattern.

### TECHNICAL FIELD

Embodiments of the present disclosure relate to a power module and a manufacturing method therefor, and more particularly, to a power module having a structure in which a spacer-integrated ceramic substrate and a lead frame-integrated ceramic substrate are stacked, and a manufacturing method of a power module.

### BACKGROUND ART

A power module is a semiconductor module optimized for power conversion or control by modularizing semiconductor elements into a package.

The power module has a structure in which a substrate is arranged on a base plate and the semiconductor elements are arranged on the substrate.

In the existing power module, the semiconductor elements are electrically connected to the substrate by wire bonding (bond-wire) made of gold (Au), copper (Cu), or aluminum (Al), and the substrate is also connected to a printed circuit board (PCB) by wire bonding. That is, a power transmission line for electrical signal and power conversion is formed by wire bonding.

However, according to such a wire bonding structure, since short-circuit or disconnection may occur due to high-power and high-current electrical energy, it is a potential risk factor for an entire vehicle and it is difficult to effectively dissipate heat generated from the semiconductor element.

The contents described in the Background Art are to help the understanding of the background of the disclosure, and may include contents that are not a disclosed conventional technology.

### DISCLOSURE

### Technical Problem

An object of the present disclosure is to provide a power module where a spacer- integrated ceramic substrate is arranged on an upper portion of the power module with a semiconductor chip therebetween, and a lead frame-integrated ceramic substrate is arranged on a lower portion thereof, thereby maximizing a heat dissipation effect, easily controlling the thickness of a lead frame, and improving electrical characteristics, and a manufacturing method therefor.

### Technical Solution

A power module according to an embodiment of the present disclosure may include: a first ceramic substrate comprising a first ceramic material and a first circuit pattern formed on at least one surface of the first ceramic material; an electrode pattern part formed on the first circuit pattern and bonded to an electrode of a semiconductor chip mounted on the first ceramic substrate; a second ceramic substrate arranged below the first ceramic substrate while being spaced from the first ceramic substrate and comprising a second ceramic material and a second circuit pattern formed on at least one surface of the second ceramic material; a lead frame arranged between the first ceramic substrate and the second ceramic substrate and bonded to the second circuit pattern; and a spacer arranged between the first circuit pattern and the lead frame to space the first circuit pattern from the lead frame.

The electrode pattern part may be formed by protruding a remaining area except for a part of the first circuit pattern that is half-etched, and may be formed with an area corresponding to the electrode of the semiconductor chip.

The spacer may have a height greater than a combined height of the electrode pattern part and the semiconductor chip.

The lead frame may be bonded to the second ceramic substrate by one of brazing, welding, and Ag sintering bonding methods.

The spacer may be made of a material such as Cu or CuMo or may be made of a CPC material in which Cu, CuMo, and Cu are sequentially stacked.

A manufacturing method of a power module according to an embodiment of the present disclosure may include: preparing a first ceramic substrate comprising a first ceramic material, a first circuit pattern formed on at least one surface of the first ceramic material, and an electrode pattern part formed on the first circuit pattern; bonding an electrode of a semiconductor chip to the electrode pattern part; bonding one surface of a spacer to the first circuit pattern; preparing a second ceramic substrate comprising a second ceramic substrate, a second circuit pattern formed on at least one surface of the second ceramic substrate, and a lead frame bonded to the second circuit pattern; and bonding the other surface of the spacer to the lead frame.

The preparing of the first ceramic substrate may include: bonding a metal layer to at least one surface of the first ceramic material; forming the first circuit pattern by etching the metal layer; and half-etching a part of the first circuit pattern to form the electrode pattern part protruding from a remaining area except for the part.

In the preparing of the second ceramic substrate, the lead frame may be bonded to the second ceramic substrate by one of brazing, welding, and Ag sintering bonding methods.

The forming of the electrode pattern part may include: forming a photoresist on the first circuit pattern; forming a photoresist pattern by arranging a mask having a pattern corresponding to the electrode pattern part on the photoresist and exposing and developing the photoresist; half-etching a part of the first circuit pattern in a thickness direction by using the photoresist pattern as a mask; and removing the photoresist pattern.

In the half-etching, a depth of the half-etching may be half a thickness of the first circuit pattern.

In the forming of the photoresist, the photoresist may be formed by attaching a dry film photoresist onto the first circuit pattern.

In the bonding of the metal layer, the metal layer may be annealed to remove thermal stress.

The bonding of the metal layer may include: arranging a brazing filler layer having a thickness of 5 μm or more and 100 μm or less between at least one surface of the first ceramic material and the metal layer by any one of paste application, foil attachment, and P-filler; and brazing the metal layer by melting the brazing filler layer.

In the arranging of the brazing filler layer, the brazing filler layer may be made of a material comprising at least one of Ag, Cu, AgCu, and AgCuTi.

### Advantageous Effects

In the present disclosure, a power module is manufactured by preparing a first ceramic substrate being a spacer-integrated ceramic substrate, preparing a second ceramic substrate being a lead frame-integrated ceramic substrate, and then bonding the first ceramic substrate and the second ceramic substrate together, so that the thickness of a lead frame can be easily controlled at a power module assembly stage, miniaturization is possible, electrical characteristics can be improved through the lead frame, and a heat dissipation effect can be increased.

In addition, in the present disclosure, an electrode pattern part can be formed on one surface of a first ceramic substrate to serve as a power transmission line for electrical signal and power conversion. Accordingly, the present disclosure can not only omit wire bonding, but also secure both multi-quantity connection of semiconductor chips and heat dissipation effect by being applied to a power module, and can also contribute to miniaturization, so that the performance of the power module can be further improved.

In addition, in the present disclosure, an electrode pattern part is an integral part not separated from a first circuit pattern, thereby improving electrical conductivity is improved and resistance characteristics. In addition, since there is no need to bond to the electrode pattern part by soldering, sintering, etc., when the electrode pattern part is formed, a gap that may occur at a bonding surface during bonding can be minimized.

In addition, in the present disclosure, even though semiconductor chips are concentrated in multiple and large quantities for miniaturization of a power module, heat generated from the semiconductor chips can be released not only to a first ceramic substrate but also to a lead frame and a second ceramic substrate, so that heat dissipation characteristics can be maximized.

### DESCRIPTION OF DRAWINGS

FIG. 1 is a bottom view illustrating a power module according to an embodiment of the present disclosure.

FIG. 2 is a cross-sectional view taken along line A-A′ in FIG. 1.

FIG. 3 is a side view schematically illustrating a state in which a semiconductor chip is bonded to the power module according to an embodiment of the present disclosure.

FIG. 4 is a bottom view illustrating a first ceramic substrate in the power module according to an embodiment of the present disclosure.

FIG. 5 is a side view illustrating the first ceramic substrate in FIG. 4.

FIG. 6 is a cross-sectional view taken along line B-B′in FIG. 4.

FIG. 7 is a side view illustrating a state in which a plurality of semiconductor chips are bonded to the first ceramic substrate in FIG. 5.

FIG. 8 is a plan view illustrating a second ceramic substrate in the power module according to an embodiment of the present disclosure.

FIG. 9 is a bottom view illustrating a lead frame in the power module according to an embodiment of the present disclosure.

FIG. 10 is a bottom view illustrating a second circuit pattern formed on an upper surface of the second ceramic substrate in a bonding structure of the lead frame and the second ceramic substrate.

FIG. 11 is a bottom view illustrating a second circuit pattern formed on a lower surface of the second ceramic substrate in the bonding structure of the lead frame and the second ceramic substrate.

FIG. 12 is a flowchart illustrating a manufacturing method of the power module according to an embodiment of the present disclosure.

FIG. 13 is a flowchart illustrating a step of preparing the first ceramic substrate in the manufacturing method of the power module according to an embodiment of the present disclosure.

FIG. 14 is a flowchart illustrating a step of forming an electrode pattern part in the step of preparing the first ceramic substrate.

FIG. 15 is a cross-sectional view illustrating a state in which a photoresist is formed on a first circuit pattern.

FIG. 16 is a cross-sectional view illustrating a state in which a mask is arranged on the photoresist and the photoresist is exposed.

FIG. 17 is a cross-sectional view illustrating a state in which an exposed photoresist is developed.

FIG. 18 is a cross-sectional view illustrating a state in which the first circuit pattern in a region with no photoresist pattern is half-etched in a thickness direction.

FIG. 19 is a cross-sectional view illustrating a state in which a remaining photoresist pattern is removed.

### MODE FOR INVENTION

Hereinafter, preferred embodiments of the present disclosure are described in detail with reference to the accompanying drawings.

Embodiments are provided to more fully explain the present disclosure to a person having ordinary knowledge in the art to which the present disclosure pertains. The following embodiments may be modified in various other forms, and the scope of the present disclosure is not limited to the following embodiments. Rather, these embodiments are provided to make the present disclosure more thorough and complete and to fully convey the spirit of the present disclosure.

Terms used in this specification are used to describe a specific embodiment, and are not intended to limit the present disclosure. Furthermore, in this specification, an expression of the singular number may include an expression of the plural number unless clearly defined otherwise in the context.

In the description of the embodiments, when it is described that each layer (film), area, pattern, or structure is formed “on” or “under” each substrate, layer (film), area, pad, or pattern, this includes both expressions, including that a layer is formed on another layer “directly” or “with a third layer interposed between the two layers (indirectly)”. Furthermore, a criterion for the term “on or under of each layer” is described based on the drawings.

The power module is an electronic component in the form of a package made up of various components, and may include a plurality of substrates and a plurality of semiconductor chips.

The present disclosure is characterized by a power module having a multi-layer structure, which is composed of a first ceramic substrate, which is a spacer-integrated ceramic substrate, and a second ceramic substrate, which is a lead frame-integrated ceramic substrate, among the components included in the power module, so this will be mainly described.

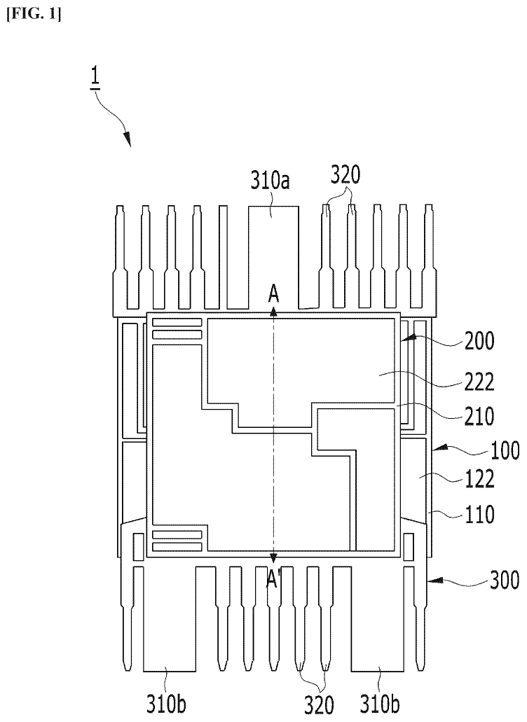

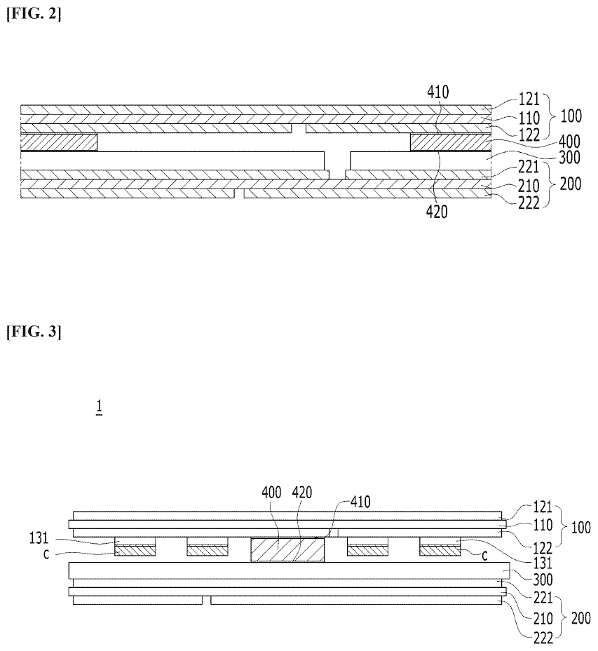

FIG. 1 is a bottom view illustrating a power module according to an embodiment of the present disclosure, FIG. 2 is a cross-sectional view taken along line A-A′ in FIG. 1, and FIG. 3 is a side view schematically illustrating a state in which a semiconductor chip is bonded to the power module according to an embodiment of the present disclosure.

Referring to FIGS. 1 to 3, a power module 1 according to an embodiment of the present disclosure has a multilayer structure in which a first ceramic substrate 100 and a second ceramic substrate 200 are arranged at a certain interval, and as will be described below, the first ceramic substrate 100 may be referred to as a spacer-integrated ceramic substrate because a spacer 400 is bonded to the first ceramic substrate 100, and the second ceramic substrate 200 may be referred to as a lead frame-integrated ceramic substrate because a lead frame 300 is bonded to the second ceramic substrate 200./A semiconductor chip c may be mounted on the first ceramic substrate 100 and arranged to face the lead frame 300 bonded to the second ceramic substrate 200. The semiconductor chip c may be a SiC chip, a GaN chip, or a Si chip that can satisfy requirements such as a high-power switch, a high-speed switch, power loss minimization, and a small chip size. In addition, various elements such as a metal oxide semiconductor field effect transistor (MOSFET), an insulated gate bipolar transistor (IGBT), a junction field effect transistor (JFET), a high electric mobility transistor (HEMT), and a fast recovery diode (FRD) may be used. In this way, the power module 1 according to an embodiment of the present disclosure is a dual-side cooling (DSC) type power module where a spacer-integrated ceramic substrate is arranged an upper portion of the power module with a semiconductor chip c therebetween and a lead frame-integrated ceramic substrate is arranged a lower portion thereof. The dual-side cooling type power module may maximize a heat dissipation effect compared to a single-side cooling type power module.

The power module 1 according to an embodiment of the present disclosure has a characteristic in that the lead frame 300 is assembled in a state of being integrally bonded to the second ceramic substrate 200. That is, in the related art, since a separate lead frame 300 is additionally bonded after assembling a double-sided cooling power module including a pair of ceramic substrates, it is difficult to easily control the thickness of a power module including a lead frame at a power module assembly stage. On the other hand, the power module 1 according to an embodiment of the present disclosure is manufactured by preparing the first ceramic substrate 100 being a spacer-integrated ceramic substrate, preparing the second ceramic substrate 200 being a lead frame- integrated ceramic substrate, and then bonding the first ceramic substrate 100 and the second ceramic substrate 200 together, so that the thickness of the lead frame 300 can be easily controlled at a power module assembly stage and miniaturization is possible. In addition, the power module 1 according to an embodiment of the present disclosure has the advantage of being able to improve electrical characteristics through the lead frame 300 and increasing a heat dissipation effect.

The first ceramic substrate 100 and the second ceramic substrate 200 may be any one of an active metal brazing (AMB) substrate, a direct bonding copper (DBC) substrate, a thick printing copper (TPC) substrate, and a direct brazed aluminum (DBA) substrate. Among these substrates, since the AMB substrate has excellent durability and heat dissipation efficiency, the first ceramic substrate 100 and the second ceramic substrate 200 are AMB substrates, for example.

As an example, the first ceramic substrate 100 may include a first ceramic material 110 and first circuit patterns 121 and 122 formed on at least one surface of the first ceramic material 110. The first ceramic material 110 may be any one of alumina (Al₂O₃), AlN, SiN, and Si₃N₄, for example.

The first circuit patterns 121 and 122 may be formed on both surfaces of the first ceramic material 110. Both surfaces of the first ceramic material 110 may mean an upper surface and a lower surface of the first ceramic material 110. The first circuit patterns 121 and 122 may each be made of at least one of Cu, Al, AlSiC, CuMo, CuW, Cu/CuMo/Cu, Cu/Mo/Cu, and Cu/W/Cu, or a composite material thereof. The first circuit patterns 121 and 122 may be formed by brazing a metal layer made of at least one of Cu, Al, AlSiC, CuMo, CuW, Cu/CuMo/Cu, Cu/Mo/Cu, and Cu/W/Cu or a composite material thereof on the first ceramic material 110, and then etching the metal layer. The thickness of the first ceramic material 110 may be 0.32 t, and the thickness of the first circuit patterns 121 and 122 may each be 0.3 t. That is, the thickness of the first circuit pattern 121 formed on the upper surface of the first ceramic material 110 and the thickness of the first circuit pattern 122 formed on the lower surface of the first ceramic material 110 may be the same.

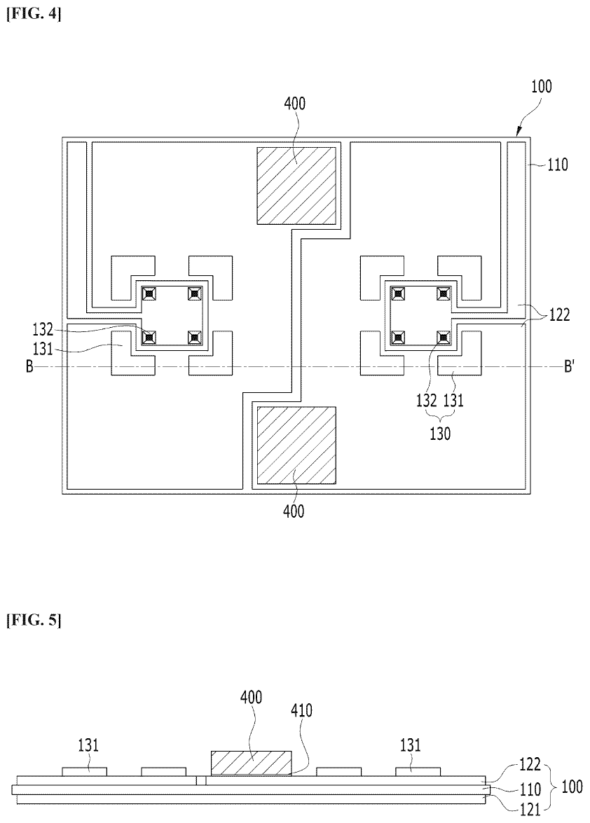

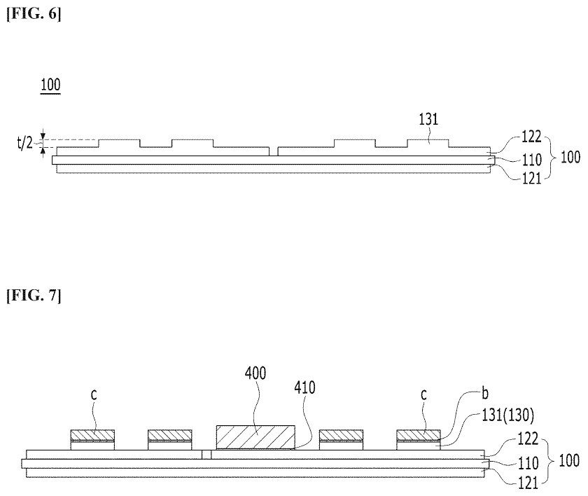

FIG. 4 is a bottom view illustrating the first ceramic substrate in the power module according to an embodiment of the present disclosure, and FIG. 5 is a side view illustrating the first ceramic substrate in FIG. 4.

Referring to FIGS. 4 and 5, the first circuit pattern 122 formed on the lower surface of the first ceramic material 110 may include an electrode pattern part 130 bonded to an electrode (not illustrated) of the semiconductor chip c. Specifically, the electrode pattern part 130 may include a first electrode pattern portion 131 and a second electrode pattern portion 132. The first electrode pattern portion 131 may be connected to a source electrode of the semiconductor chip c, and the second electrode pattern portion 132 may be connected to a gate electrode of the semiconductor chip c. The source electrode of the semiconductor chip c is a terminal that is responsible for input/output of high current, and the gate electrode of the semiconductor chip c is a terminal that turns on/off the semiconductor chip c by using a low voltage.

The electrode pattern part 130 may be provided in a plural number in consideration of the number and locations of electrodes of the semiconductor chip c to be bonded to the electrodes of the semiconductor chip c. Since such an electrode pattern part 130 is electrically connected to the electrodes of the semiconductor chip c, it may serve as a power transmission line for electrical signal and power conversion.

The spacer 400 may be bonded to a remaining area of the first circuit pattern 122 except for an area where the electrode pattern part 130 is formed, and may perform a function of spacing the first ceramic substrate 100 from the lead frame 300 arranged below the first ceramic substrate 100 and increasing heat dissipation efficiency. That is, when the first circuit pattern 122 on which the semiconductor chip c is mounted is connected to the lead frame 300 and the spacer 400 having thermal conductivity, heat generated from the semiconductor chip c is not only released to the first ceramic substrate 100 through the spacer 400, but also to the lead frame 300 and the second ceramic substrate 200, enabling quick heat dissipation.

In this way, since the spacer 400 is arranged between the first circuit pattern 122 and the lead frame 300 to space the first circuit pattern 122 from the lead frame 300 and performs a heat dissipation and support function, the spacer 400 may have a height greater than the combined height of the electrode pattern part 130 and the semiconductor chip c mounted on the electrode pattern part 130. For example, when the height of the electrode pattern part 130 is 0.5 mm and the height of the semiconductor chip c is 150 μm to 180 μm, the spacer 400 may be formed to have a height of 0.7 mm higher than the combined height of the electrode pattern part 130 and the semiconductor chip c. In addition, the spacer 400 may be formed in various shapes such as a square block shape or a cylindrical shape.

The spacer 400 may be made of a material such as Cu or CuMo, or may be made of a CPC material in which Cu, CuMo, and Cu are sequentially stacked. The material of the spacer 400 may be selected from materials having electrical conductivity and a thermal expansion coefficient that satisfy conditions.

The spacer 400 may be bonded to the first circuit pattern 122 of the first ceramic substrate 100 via a first bonding layer 410. The first bonding layer 410 may be an Ag sintering bonding layer. The first bonding layer 410 may be formed by applying Ag sintering paste, or by transferring the Ag sintering paste using a film on which the Ag sintering paste is printed, etc. Such a first bonding layer 410 may be arranged between the first circuit pattern 122 and one surface of the spacer 400, and the spacer 400 may be sintered and bonded to the first circuit pattern 122 via the first bonding layer 410. The temperature of a heating furnace during sintering and bonding may vary depending on the components of the bonding layer, but the sintering and bonding may be preferably performed at a temperature of 200° C. to 250° C., and in such a case, a pressure of 10 MPa to 15 MPa may be applied.

Since the spacer 400 has a certain size, it can be manufactured by mechanical processing such as wire cutting or forging. Since the electrode pattern part 130 is relatively small in size, it may be formed by etching. When the second electrode pattern portion 132 having a relatively smaller size of the electrode pattern part 130 is formed by etching, it may be formed in a square pyramid shape whose cross-sectional area is reduced upward.

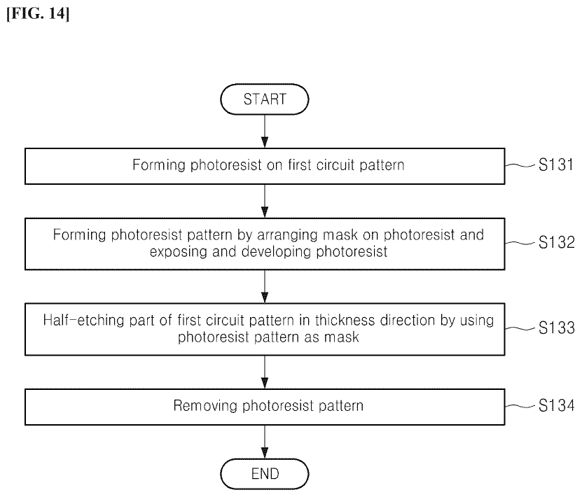

Referring to FIG. 6, the electrode pattern part 130 may be formed by protruding a remaining area except for a part of the first circuit pattern 122 that is half-etched. The depth at which a part of the first circuit pattern 122 is half-etched may be half a thickness t of the first circuit pattern 122, and in such a case, the thickness of the electrode pattern part 130 being the remaining area except for the part may be half (t/2) the thickness of the first circuit pattern 122. The process of forming the electrode pattern part 130 by half-etching a part of the first circuit pattern 122 is described below in detail with reference to FIGS. 14 to 19.

The electrode pattern part 130 formed by half-etching a part of the first circuit pattern 122 is an integral part not separated from the first circuit pattern 122, thereby improving the electrical conductivity and the resistance characteristics. In addition, since there is no need to bond to the electrode pattern part 130 by soldering, sintering, etc., when the electrode pattern part 130 is formed, a gap that may occur at a bonding surface during bonding can be minimized. In addition, since heat generated from the semiconductor chip c can be easily transferred to the first ceramic substrate 100, a heat sink (not illustrated) coupled to the first ceramic substrate 100, etc., through the electrode pattern part 130, the heat dissipation efficiency can be increased.

FIG. 7 is a side view illustrating a state in which a plurality of semiconductor chips are bonded to the first ceramic substrate in FIG. 5.

Referring to FIG. 7, each of a plurality of semiconductor chips c may be bonded to a corresponding electrode pattern part 130 via a bonding layer b. The bonding layer b is for bonding an electrode of the semiconductor chip c and one surface of each electrode pattern part 130, and may include solder or silver paste (Ag Paste).

The solder may be made of a SnPb-based, SnAg-based, SnAgCu-based, or Cu-based solder paste having high bonding strength and excellent high-temperature reliability. The silver paste has better high-temperature reliability and higher thermal conductivity than the solder. The silver paste may include 90 wt % to 99 wt % of Ag powder and 1 wt % to 10 wt % of binder to have high thermal conductivity. The Ag powder may be nanoparticles. The Ag powder being nanoparticles can be sintered at a low temperature, has high thermal conductivity, and has high bonding density.

Although not illustrated in detail, each of the first electrode pattern portion 131 and the second electrode pattern portion 132 may be formed with an area corresponding to an electrode area of the semiconductor chip c to be bonded. Each of the first electrode pattern portion 131 and the second electrode pattern portion 132 may have a size of 0.5 mm or more and a thickness of 0.3 mm or more, but is not limited thereto.

In this way, the electrode pattern part 130 is formed to be bonded to the electrode of the semiconductor chip c, so that the semiconductor chip c is mounted on the first ceramic substrate 100 in a form similar to a flip chip. That is, when the semiconductor chip c is bonded to the electrode pattern part 130 of the first ceramic substrate 100, a power transmission path is shortened, so that electrical loss and load due to resistance on the power transmission path can be reduced. In addition, since the electrode pattern part 130 may serve as a power transmission line for electrical signal and power conversion instead of the wire bonding in the related art, the wire bonding can be omitted. When the wire bonding is omitted, an inductance value decreases, so that heat dissipation performance is also improved. In addition, while eliminating electrical risk factors that may occur during the wire bonding, the conversion of rated voltage and current using a semiconductor chip can be stable, thereby increasing reliability and efficiency when used at high power.

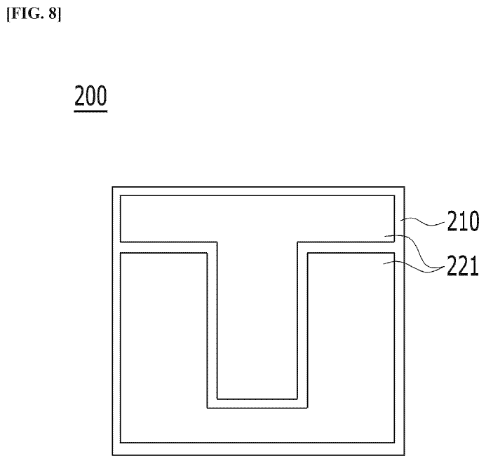

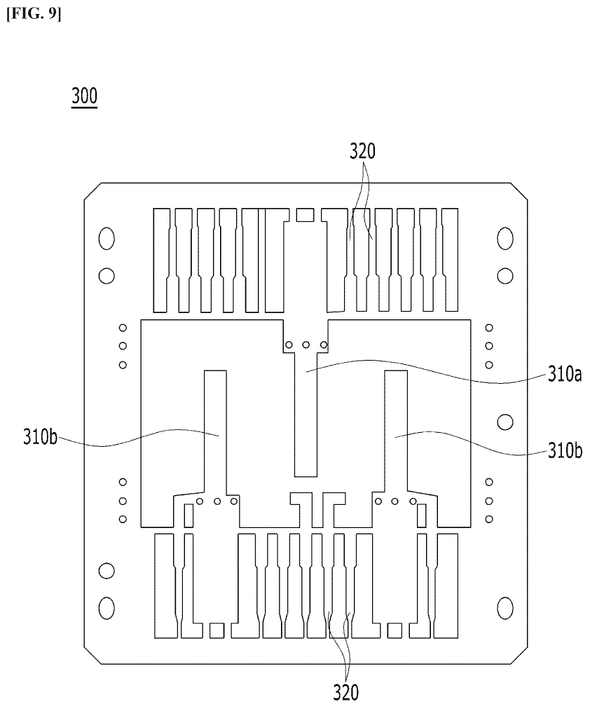

FIG. 8 is a plan view illustrating the second ceramic substrate in the power module according to an embodiment of the present disclosure.

Referring to FIG. 8, the second ceramic substrate 200 may include a second ceramic material 210 and second circuit patterns 221 and 222 formed on at least one surface of the second ceramic material 210. The second ceramic material 210 may be one of alumina (Al₂O₃), AIN, SiN, and Si₃N₄, for example.

The second circuit pattern 221 and 222 may be formed on both surfaces of the second ceramic material 210. The two surfaces of the second ceramic material 210 may mean an upper surface and a lower surface of the second ceramic material 210. The second circuit pattern 221 and 222 may each be made of at least one of Cu, Al, AlSiC, CuMo, CuW, Cu/CuMo/Cu, Cu/Mo/Cu, and Cu/W/Cu, or a composite material thereof. The second circuit pattern 221 and 222 may be formed by brazing a metal layer made of at least one of Cu, Al, AlSiC, CuMo, CuW, Cu/CuMo/Cu, Cu/Mo/Cu, and Cu/W/Cu or a composite material thereof on the second ceramic material 210, and then etching the metal layer. The thickness of the second ceramic material 210 may be 0.32 t, and the thickness of the second circuit pattern 221 and 222 may each be 0.3 t. That is, the thickness of the second circuit pattern 221 formed on the upper surface of the second ceramic material 210 and the thickness of the second circuit pattern 222 formed on the lower surface of the second ceramic material 210 may be the same.

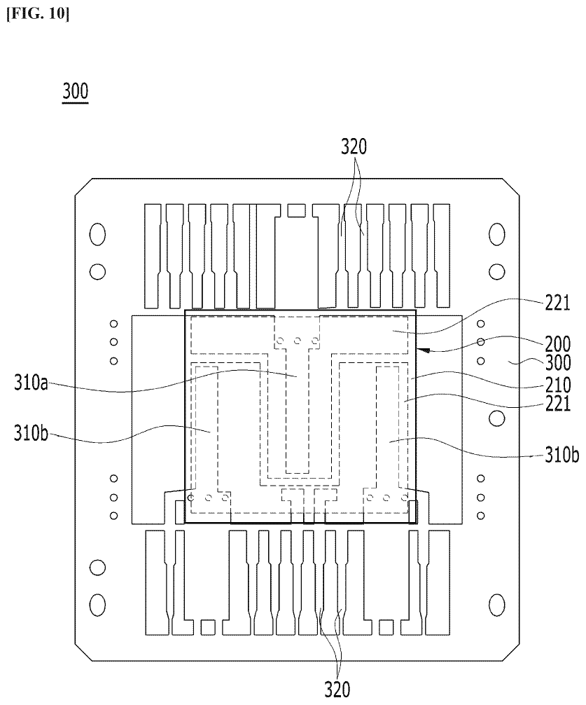

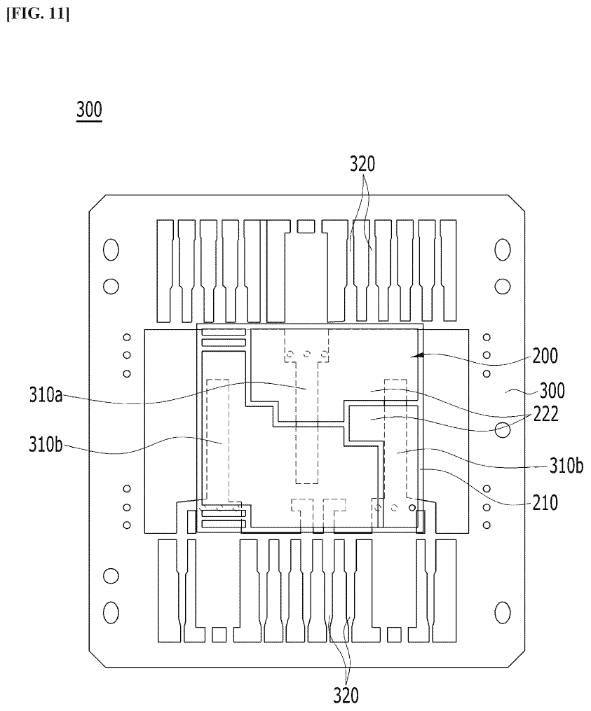

FIG. 9 is a bottom view illustrating the lead frame in the power module according to an embodiment of the present disclosure, FIG. 10 is a bottom view illustrating the second circuit pattern formed on the upper surface of the second ceramic substrate in the bonding structure of the lead frame and the second ceramic substrate, and FIG. 11 is a bottom view illustrating the second circuit pattern formed on the lower surface of the second ceramic substrate in the bonding structure of the lead frame and the second ceramic substrate.

Referring to FIG. 9, the lead frame 300 is a kind of frame having a circuit installed therein to connect electric signals of an electronic material, and is initially manufactured as an integral body as illustrated in FIG. 9, but may be trimmed like the lead frame 300 of FIG. 1. The lead frame 300 may be arranged between the first ceramic substrate 100 and the second ceramic substrate 200, and may be bonded to the second circuit pattern 221.

As illustrated in FIG. 1, FIG. 9, and FIG. 10, the lead frame 300 may include a first lead portion 310a, second lead portions 310b, and a third lead portion 320. Referring to FIG. 10, the first lead portion 310a and the second lead portion 310b are portions bonded to the second circuit pattern 221 formed on the upper surface of the second ceramic substrate 200. The second lead portion 310b may be arranged on both sides and bonded to the same circuit pattern, and the first lead portion 310a arranged between the second lead portions 310b may be bonded to another circuit pattern. In this way, since the first lead portion 310a and the second lead portion 310b are bonded to different circuit patterns, the first lead portion 310a and the second lead portion 310b may be manufactured to be separated in a circuit configuration during trimming. The third lead portion 320 may be trimmed into the shape of a transmission pin. The lead frame 300 may be made of a material such as Cu or Al, and may be manufactured by mold processing, etc., for height control. The lead frame 300 may be manufactured to have a height of 0.5 mm or more.

Referring to FIG. 11, the second circuit pattern 222 of the second ceramic substrate 200 formed on a surface opposite to the surface bonded to the lead frame 300, in other words, the second circuit pattern 222 formed on the lower surface of the second ceramic material 210, may be formed in a different form from the second circuit pattern 221 illustrated in FIG. 8 and FIG. 10. The form of the second circuit pattern 222 illustrated in FIG. 11 illustrates an embodiment, and is not limited thereto and may be implemented in various forms.

The lead frame 300 may be bonded to the second ceramic substrate 200 by one of brazing, welding, and Ag sintering bonding methods. The brazing method is a method of melting a brazing filler layer at a temperature lower than the melting point of a base material of 450° C. or higher and bonding the brazing filler layer. The welding method may include laser welding, ultrasonic welding, etc., and among these, the laser welding may be mainly used. The laser welding method uses a laser beam, and two members may be melted and bonded by heat generated by the laser beam. Such a laser welding method is a non-contact welding method, which has excellent welding quality and can increase productivity. The Ag sintering bonding is a sintering bonding method in which an Ag sintering bonding layer is arranged between the lead frame 300 and the second ceramic substrate 200. The Ag sintering bonding layer may be formed by applying Ag sintering paste, or by transferring the Ag sintering paste using a film on which the Ag sintering paste is printed, etc. The temperature of a heating furnace during sintering and bonding may vary depending on the components of the bonding layer, but the sintering and bonding may be preferably performed at a temperature of 200° C. to 250° C., and in such a case, a pressure of 10 MPa to 15 MPa may be applied.

The second ceramic substrate 200 to which the lead frame 300 is integrally bonded may be bonded to the first ceramic substrate 100 being a spacer-integrated ceramic substrate as illustrated in FIG. 3. In such a case, the other surface of the spacer 400 bonded to the first ceramic substrate 100 may be bonded to the upper surface of the lead frame 300 via a second bonding layer 420. The second bonding layer 420 may be an Ag sintering bonding layer. The second bonding layer 420 may be formed by applying Ag sintering paste, or by transferring the Ag sintering paste using a film on which the Ag sintering paste is printed. Such a second bonding layer 420 may be arranged between the other surface of the spacer 400 and the lead frame 300, and the spacer 400 may be sintered and bonded to the lead frame 300 via the second bonding layer 420. The temperature of a heating furnace during sintering and bonding may vary depending on the components of the bonding layer, but the sintering and bonding may be preferably performed at a temperature of 200° C. to 250° C., and in such a case, a pressure of 10 MPa to 15 MPa may be applied.

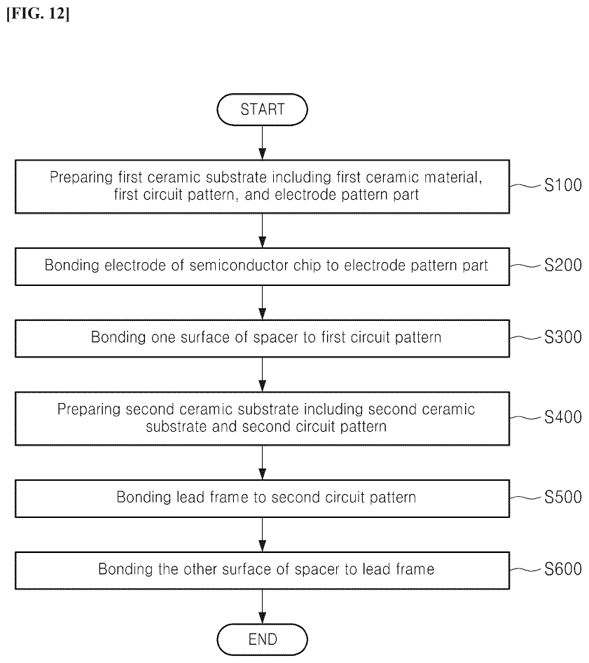

A manufacturing method of the power module according to an embodiment of the present disclosure is described below with reference to FIGS. 12 to 19.

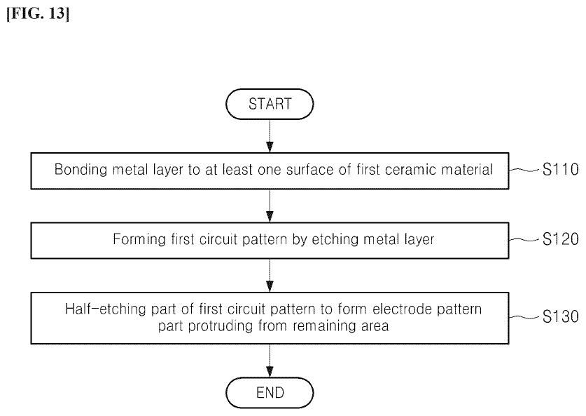

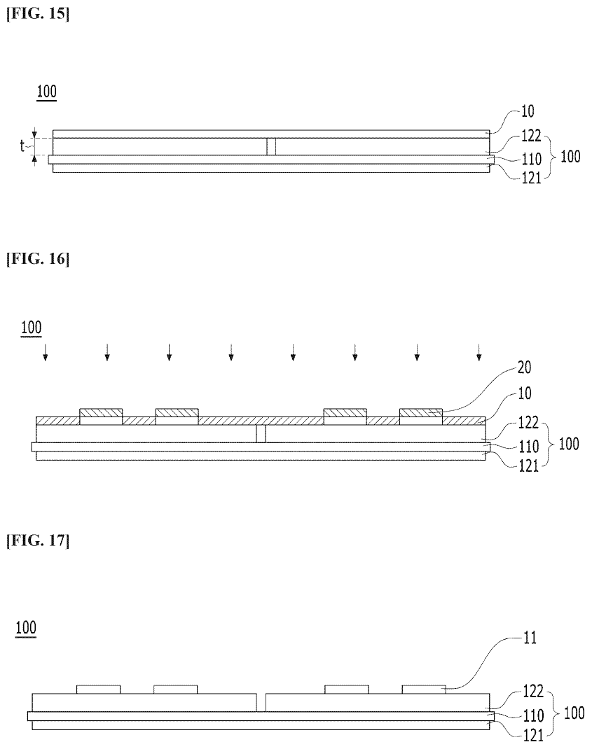

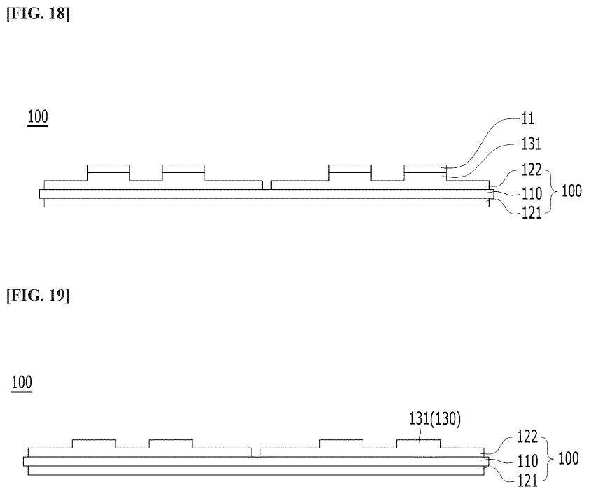

FIG. 12 is a flowchart illustrating a manufacturing method of the power module according to an embodiment of the present disclosure, FIG. 13 is a flowchart illustrating a step of preparing the first ceramic substrate in the manufacturing method of the power module according to an embodiment of the present disclosure, FIG. 14 is a flowchart illustrating a step of forming an electrode pattern part in the step of preparing the first ceramic substrate, FIG. 15 is a cross-sectional view illustrating a state in which a photoresist is formed on the first circuit pattern, FIG. 16 is a cross-sectional view illustrating a state in which a mask is arranged on the photoresist and the photoresist is exposed, FIG. 17 is a cross-sectional view illustrating a state in which an exposed photoresist is developed, FIG. 18 is a cross-sectional view illustrating a state in which the first circuit pattern in a region with no photoresist pattern is half-etched in a thickness direction, and FIG. 19 is a cross-sectional view illustrating a state in which a remaining photoresist pattern is removed.

As illustrated in FIG. 12, the manufacturing method of the power module according to an embodiment of the present disclosure includes step S100 of preparing the first ceramic substrate 100 including the first ceramic material 110, the first circuit patterns 121 and 122 formed on at least one surface of the first ceramic material 110, and the electrode pattern part 130 formed on the first circuit pattern 122, step S200 of bonding the electrode of the semiconductor chip c to the electrode pattern part 130, step S300 of bonding one surface of the spacer 400 to the first circuit pattern 122, step $400 of preparing the second ceramic substrate 200 including the second ceramic material 210, the second circuit patterns 221 and 222 formed on at least one surface of the second ceramic material 210, and the lead frame 300 bonded to the second circuit pattern 221, and step S500 of bonding the other surface of the spacer 400 to the lead frame 300. The steps may be performed sequentially or in a reverse order, or may be performed substantially simultaneously.

As illustrated in FIG. 13, step S100 of preparing the first ceramic substrate 100 may include step S110 of bonding a metal layer to at least one surface of the first ceramic material 110, step S120 of forming the first circuit patterns 121 and 122 by etching the metal layer, and step S130 of half-etching a part of the first circuit pattern 122 to form the electrode pattern part 130 protruding from a remaining area except for the part.

In step S110 of bonding the metal layer, the metal layer made of metal may be bonded to at least one surface of the first ceramic material 110 by an active metal brazing (AMB) process. The first ceramic material 110 may be one of alumina (Al₂O₃), ZTA, AIN, and Si₃N₄, for example. The metal layer may be brazed to the upper and lower surfaces of the first ceramic material 110.

In the step of bonding the metal layer S110, the metal layer may be other electrode materials such as Cu, Al, or a metal alloy. For example, the metal layer may be made of at least one of Cu, Al, AlSiC, CuMo, CuW, Cu/CuMo/Cu, Cu/Mo/Cu, and Cu/W/Cu, or a composite material thereof.

The metal layer may be in a state in which thermal stress is removed by annealing. Since the metal layer is provided to be thicker by a thickness for forming the electrode pattern part 130 through subsequent etching processing, problems such as warping may occur due to thermal stress in the process of brazing to the first ceramic material 110. Accordingly, when thermal stress, thermal deformation, etc., are removed in advance through annealing heat treatment before the metal layer is brazed to the first ceramic material 110, thermal stress generated by thermal expansion and thermal contraction during the brazing process can be alleviated. In addition, the occurrence of warping of the metal layer is minimized, so that no bonded portion is damaged and the subsequent etching processing can be smoothly performed. The temperature, time, etc., of the annealing heat treatment can be appropriately adjusted depending on the metal layer material, etc.

Step S110 of bonding the metal layer may include a step of arranging a brazing filler layer having a thickness of 5 μm or more and 100 μm or less between at least one surface of the first ceramic material 110 and the metal layer by any one of paste application, foil attachment, and P-filler, and a step of brazing the metal layer by melting the brazing filler layer.

In the step of arranging the brazing filler layer, the brazing filler layer may be made of a material including at least one of Ag, Cu, AgCu, and AgCuTi. The step of brazing the metal layer by melting the brazing filler layer may be performed at 450° C. or higher.

In step S120 of forming the first circuit patterns 121 and 122, the first circuit patterns 121 and 122 may be formed by etching the metal layer bonded to at least one surface of the first ceramic material 110, according to a designed pattern.

In step S130 of forming the electrode pattern part 130, the electrode pattern part 130 may be formed by half-etching a part of the first circuit pattern 122 by a photolithography process. Such an electrode pattern part 130 may be formed in a plural number in consideration of the number and locations of electrodes of the semiconductor chip c to be bonded to the electrodes of the semiconductor chip c. Since such an electrode pattern part 130 is electrically connected to the electrodes of the semiconductor chip c, it may serve as a power transmission line for electrical signal and power conversion.

As illustrated in FIG. 14, step S130 of forming the electrode pattern part 130 may include step S131 of forming a photoresist 10 on the first circuit pattern 122, step S132 of forming a photoresist pattern 11 by arranging a mask 20 having a pattern corresponding to the electrode pattern part 130 on the photoresist 10 and then exposing and developing the photoresist 10, step S133 of half-etching a part of the first circuit pattern 122 in the thickness direction by using the photoresist pattern 11 as a mask, and step S134 of removing the photoresist pattern 11.

As illustrated in FIG. 15, in step S131 of forming the photoresist 10, the photoresist 10 may be formed on the first circuit pattern 122 to have a predetermined thickness. The photoresist 10 may be formed by attaching a dry film photoresist onto the first circuit pattern 122. In this step, the thickness t of the first circuit pattern 122 on the surface where the electrode pattern part 130 is formed may be 0.6 t, and the thickness of the first circuit pattern 121 formed on the opposite surface may be 0.3 t.

Step S132 of forming the photoresist pattern 11 may include a step of emitting light such as ultraviolet (UV) after arranging the mask 20 having the pattern corresponding to the electrode pattern part 130 on the photoresist 10. As illustrated in FIG. 16, when the light is emitted through the mask 20, the pattern formed on the mask 20 may be transferred to the photoresist 10. A type in which only a portion exposed by the light is developed is a positive type, and a type in which only a portion not exposed by the light is developed is a negative type. The present disclosure describes an example in which a positive-type photoresist 10 is used, but a negative-type photoresist may also be used.

Step S132 of forming the photoresist pattern 11 may include a step of developing the exposed photoresist 10. When the exposed photoresist 10 is developed, only the photoresist in an area corresponding to the pattern of the mask 20 remains as illustrated in FIG. 17, so that the photoresist pattern 11 may be formed.

In step S133 of half-etching, as illustrated in FIG. 18, a part of the first circuit pattern 122 without the photoresist pattern 11 may be half-etched in the thickness direction by a process such as dry etching or wet etching. The depth of the half-etching may be half (t/2) the thickness of the first circuit pattern 122. In this way, when the first circuit pattern 122 in the area without the photoresist pattern 11 is half-etched by half of the thickness by using the photoresist pattern 11 as a mask, the first circuit pattern 122 in the area where the photoresist pattern 11 remains may protrude more than a surrounding area that has been half-etched. For example, when the thickness of the first circuit pattern 122 is 0.6 t, the first circuit pattern 122 in the area without the photoresist pattern 11 may be half-etched in the thickness direction by 0.3 t, and the first circuit pattern 122 in the area where the photoresist pattern 11 remains may protrude further by 0.3 t than the half-etched area.

In step S134 of removing the photoresist pattern 11, as illustrated in FIG. 19, the photoresist pattern 11 remaining on the electrode pattern part 130 may be removed to finally form the electrode pattern part 130.

In step S200 of bonding the electrode of the semiconductor chip c to the electrode pattern part 130, the electrode of the semiconductor chip c may be bonded to the electrode pattern part 130 via the bonding layer b. The bonding layer b is for bonding the electrode of the semiconductor chip c and one surface of the electrode pattern part 130, and may include solder or silver paste (Ag Paste). The solder may be made of a SnPb-based, SnAg-based, SnAgCu-based, or Cu-based solder paste having high bonding strength and excellent high-temperature reliability. The silver paste has better high-temperature reliability and higher thermal conductivity than the solder. The silver paste may include 90 wt % to 99 wt % of Ag powder and 1 wt % to 10 wt % of binder to have high thermal conductivity. The Ag powder may be nanoparticles. The Ag powder being nanoparticles can be sintered at a low temperature, has high thermal conductivity, and has high bonding density.

In step S300 of bonding one surface of the spacer 400 to the first circuit pattern 122, one surface of the spacer 400 may be bonded to the first circuit pattern 122 of the first ceramic substrate 100 via the first bonding layer 410. The first bonding layer 410 may be an Ag sintering bonding layer. The first bonding layer 410 may be formed by applying Ag sintering paste, or by transferring the Ag sintering paste using a film on which the Ag sintering paste is printed, etc. Such a first bonding layer 410 may be arranged between the first circuit pattern 122 and one surface of the spacer 400, and the spacer 400 may be sintered and bonded to the first circuit pattern 122 via the first bonding layer 410.

In step S400 of preparing the second ceramic substrate 200 including the second ceramic material 210, the second circuit patterns 221 and 222 formed on at least one surface of the second ceramic material 210, and the lead frame 300 bonded to the second circuit, a metal layer may be bonded to at least one surface of the second ceramic material 210 and the second circuit pattern 221 and 222 may be formed by etching the metal layer. The second ceramic material 210 may be one of alumina (Al₂O₃), AlN, SiN, and Si₃N₄, for example, and the metal layer may be made of at least one of Cu, Al, AlSiC, CuMo, CuW, Cu/CuMo/Cu, Cu/Mo/Cu, and Cu/W/Cu, or a composite material thereof.

In step S400 of preparing the second ceramic substrate 200, the lead frame 300 may be bonded to the second ceramic substrate 200 by one of brazing, welding, and Ag sintering bonding methods. The brazing method is a method of melting a brazing filler layer at a temperature lower than the melting point of a base material of 450° C. or higher and bonding the brazing filler layer. The welding method may include laser welding, ultrasonic welding, etc., and among these, the laser welding may be mainly used. The laser welding method uses a laser beam, and two members may be melted and bonded by heat generated by the laser beam. Such a laser welding method is a non-contact welding method, which has excellent welding quality and can increase productivity. The Ag sintering bonding is a sintering bonding method in which an Ag sintering bonding layer is arranged between the lead frame 300 and the second ceramic substrate 200. The Ag sintering bonding layer may be formed by applying Ag sintering paste, or by transferring the Ag sintering paste using a film on which the Ag sintering paste is printed, etc.

In step S500 of bonding the other surface of the spacer 400 to the lead frame 300, the other surface of the spacer 400 may be bonded to the upper surface of the lead frame 300 via the second bonding layer 420. The second bonding layer 420 may be an Ag sintering bonding layer. The second bonding layer 420 may be formed by applying Ag sintering paste, or by transferring the Ag sintering paste using a film on which the Ag sintering paste is printed, etc. Such a second bonding layer 420 may be arranged between the other surface of the spacer 400 and the lead frame 300, and the spacer 400 may be sintered to the lead frame 300 via the second bonding layer 420.

In this way, the power module 1 according to an embodiment of the present disclosure is manufactured by preparing the first ceramic substrate 100 being a spacer-integrated ceramic substrate, and the second ceramic substrate 200 being a lead frame-integrated ceramic substrate, and then bonding the first ceramic substrate 100 and the second ceramic substrate 200 together, so that the thickness of the lead frame 300 can be easily controlled during the assembly stage of the power module, and miniaturization is possible. In addition, the power module 1 according to an embodiment of the present disclosure has the advantage of being able to improve electrical characteristics through the lead frame 300 and increasing a heat dissipation effect.

In addition, since the first circuit pattern 122 on which the semiconductor chip c is mounted is connected to the lead frame 300 by the spacer 400 having thermal conductivity, heat generated from the semiconductor chip c is not only released to the first ceramic substrate 100, but also to the lead frame 300 and the second ceramic substrate 200, enabling quick heat dissipation.

In addition, in the power module according to an embodiment of the present disclosure, the first circuit patterns 121 and 122 can be formed by etching the metal layer bonded to the first ceramic material 110, and the electrode pattern part 130 having a desired thickness can be formed by etching a part of the first circuit pattern 122 again. Since such an electrode pattern part 130 is integrated with the first circuit pattern 122, thereby improving the electrical conductivity and the resistance characteristics. In addition, since there is no need to bond to the electrode pattern part by soldering, sintering, etc., when the electrode pattern part is formed, a gap that may occur at a bonding surface during bonding can be minimized.

As described above, although several embodiments have been described, it is to be understood that the present disclosure may be modified in various ways. For example, proper results may be achieved although the above descriptions are performed in order different from that of the described method and/or the aforementioned components, such as the system, structure, device or apparatus, and circuit, are combined in a form different from that of the described method or rearranged with or supplemented by other components or equivalents. Accordingly, other implementations of the claims fall within the scope of the claims.

1. A power module comprising:
a first ceramic substrate comprising a first ceramic material and a first circuit pattern formed on at least one surface of the first ceramic material;
an electrode pattern part formed on the first circuit pattern and bonded to an electrode of a semiconductor chip mounted on the first ceramic substrate;
a second ceramic substrate arranged below the first ceramic substrate while being spaced from the first ceramic substrate and comprising a second ceramic material and a second circuit pattern formed on at least one surface of the second ceramic material;
a lead frame arranged between the first ceramic substrate and the second ceramic substrate and bonded to the second circuit pattern; and
a spacer arranged between the first circuit pattern and the lead frame to space the first circuit pattern from the lead frame.

2. The power module of claim 1, wherein the electrode pattern part is formed by protruding a remaining area except for a part of the first circuit pattern that is half-etched.

3. The power module of claim 1, wherein the spacer has a height greater than a combined height of the electrode pattern part and the semiconductor chip.

4. The power module of claim 1, wherein the electrode pattern part is formed with an area corresponding to the electrode of the semiconductor chip.

5. The power module of claim 1, wherein the lead frame is bonded to the second ceramic substrate by one of brazing, welding, and Ag sintering bonding methods.

6. The power module of claim 1, wherein the spacer is made of a material such as Cu or CuMo or is made of a CPC material in which Cu, CuMo, and Cu are sequentially stacked.

7. A manufacturing method of a power module, comprising:
preparing a first ceramic substrate comprising a first ceramic material, a first circuit pattern formed on at least one surface of the first ceramic material, and an electrode pattern part formed on the first circuit pattern;
bonding an electrode of a semiconductor chip to the electrode pattern part;
bonding one surface of a spacer to the first circuit pattern;
preparing a second ceramic substrate comprising a second ceramic substrate, a second circuit pattern formed on at least one surface of the second ceramic substrate, and a lead frame bonded to the second circuit pattern; and
bonding the other surface of the spacer to the lead frame.

8. The manufacturing method of a power module of claim 7, wherein the preparing of the first ceramic substrate comprises:
bonding a metal layer to at least one surface of the first ceramic material;
forming the first circuit pattern by etching the metal layer; and
half-etching a part of the first circuit pattern to form the electrode pattern part protruding from a remaining area except for the part.

9. The manufacturing method of a power module of claim 7, wherein in the preparing of the second ceramic substrate, the lead frame is bonded to the second ceramic substrate by one of brazing, welding, and Ag sintering bonding methods.

10. The manufacturing method of a power module of claim 8, wherein the forming of the electrode pattern part comprises:
forming a photoresist on the first circuit pattern;
forming a photoresist pattern by arranging a mask having a pattern corresponding to the electrode pattern part on the photoresist and exposing and developing the photoresist;
half-etching a part of the first circuit pattern in a thickness direction by using the photoresist pattern as a mask; and
removing the photoresist pattern.

11. The manufacturing method of a power module of claim 10, wherein in the half-etching, a depth of the half-etching is half a thickness of the first circuit pattern.

12. The manufacturing method of a power module of claim 10, wherein in the forming of the photoresist, the photoresist is formed by attaching a dry film photoresist onto the first circuit pattern.

13. The manufacturing method of a power module of claim 8, wherein in the bonding of the metal layer, the metal layer is annealed to remove thermal stress.

14. The manufacturing method of a power module of claim 8, wherein the bonding of the metal layer comprises:
arranging a brazing filler layer having a thickness of 5 μm or more and 100 μm or less between at least one surface of the first ceramic material and the metal layer by any one of paste application, foil attachment, and P-filler; and
brazing the metal layer by melting the brazing filler layer.

15. The manufacturing method of a power module of claim 14, wherein in the arranging of the brazing filler layer, the brazing filler layer is made of a material comprising at least one of Ag, Cu, AgCu, and AgCuTi.
